(19) United States
(12) Patent Application Publication
(10) Pub. No.: US 2023/0207421 A1
(43) Pub. Date: Jun. 29, 2023

(54) TECHNOLOGIES FOR THERMOELECTRIC-ENHANCED COOLING

(71) Applicant: Intel Corporation, Santa Clara, CA (US)

(72) Inventors: Han Wui Then, Portland, OR (US); Marko Radosavljevic, Portland, OR (US); Sansaptak Dasgupta, Portland, OR (US); Paul Fischer, Portland, OR (US); Walid M. Hafez, Portland, OR (US)

(73) Assignee: Intel Corporation, Santa Clara, CA (US)

(21) Appl. No.: 17/561,463

(22) Filed: Dec. 23, 2021

(51) Int. Cl. H01L 23/38; H01L 27/16; H01L 35/34

(52) U.S. Cl. CPC H01L 23/38; H01L 27/16; H01L 35/34

(57) ABSTRACT

Technologies for thermoelectric enhanced cooling on an integrated circuit die are disclosed. In the illustrative embodiment, one or more components are created on a top side of an integrated circuit die, such as a power amplifier, logic circuitry, etc. The one or more components, in use, generate heat that needs to be carried away from the components. A thermoelectric cooler can be created on a back side of the die in order to facilitate removal of heat from the component. In some embodiments, additional structures such as vias filled with high-thermal-conductivity material may be used to further improve the removal of heat from the component.

### BACKGROUND

Components such as processors, power amplifiers, or power components can dissipate large amounts of heat, which must be removed to prevent the components from overheating. A heatsink or heat spreader may be used to extract heat from a die. In some cases, a heatsink may interfere with components on the die or may not be able to extract heat quickly enough. In some cases, heat can be removed from a back side of a die. However, the relatively high thermal resistance due to factors such as the thickness of the die can limit the effectiveness of cooling a die by removing heat from the back side of the die.

### BRIEF DESCRIPTION OF THE DRAWINGS

FIG. 1 is a top-down view of a system with a thermoelectric cooler on a back side of a die.

FIG. 2 is a cross-sectional side view of the system of FIG. 1.

FIG. 3 is a cross-sectional side view of a system with a thermoelectric cooler on a back side of a die.

FIG. 4 is a cross-sectional side view of a system with a thermoelectric cooler on a back side of a die.

FIG. 5 is a simplified flow diagram of at least one embodiment of a method for manufacturing a die with a thermoelectric cooler on the back side.

FIG. 6 shows a die at one step of the method of manufacture of the flow diagram of FIG. 5.

FIG. 7 shows a die at one step of the method of manufacture of the flow diagram of FIG. 5.

FIG. 8 shows a die at one step of the method of manufacture of the flow diagram of FIG. 5.

FIG. 9 shows a die at one step of the method of manufacture of the flow diagram of FIG. 5.

FIG. 10 shows a die at one step of the method of manufacture of the flow diagram of FIG. 5.

FIG. 11 shows a die at one step of the method of manufacture of the flow diagram of FIG. 5.

FIG. 12 shows a die at one step of the method of manufacture of the flow diagram of FIG. 5.

FIG. 13 shows a die at one step of the method of manufacture of the flow diagram of FIG. 5.

FIG. 14 is a top view of a wafer and dies that may be included in a microelectronic assembly, in accordance with any of the embodiments disclosed herein.

FIG. 15 is a cross-sectional side view of an integrated circuit device that may be included in a microelectronic assembly, in accordance with any of the embodiments disclosed herein.

FIGS. 16A-16D are perspective views of example planar, gate-all-around, and stacked gate-all-around transistors.

FIG. 17 is a cross-sectional side view of an integrated circuit device assembly that may include a microelectronic assembly, in accordance with any of the embodiments disclosed herein.

FIG. 18 is a block diagram of an example electrical device that may include a microelectronic assembly, in accordance with any of the embodiments disclosed herein.

### DETAILED DESCRIPTION

In various embodiments disclosed herein, a thermoelectric cooler can be formed on the back side of an integrated circuit die after components are first formed on the front side of the die. An integrated thermoelectric cooler can be relatively close to the components on the front side, reducing the thermal resistance due to a thick substrate. In some cases, vias filled with high-thermal-conductivity material can be used to increase the cooling power of the thermoelectric cooler. The thermoelectric cooler can improve and accelerate cooling of components on the top side of the die, can be targeted to areas of a die with high heat generation, and can be employed on demand.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

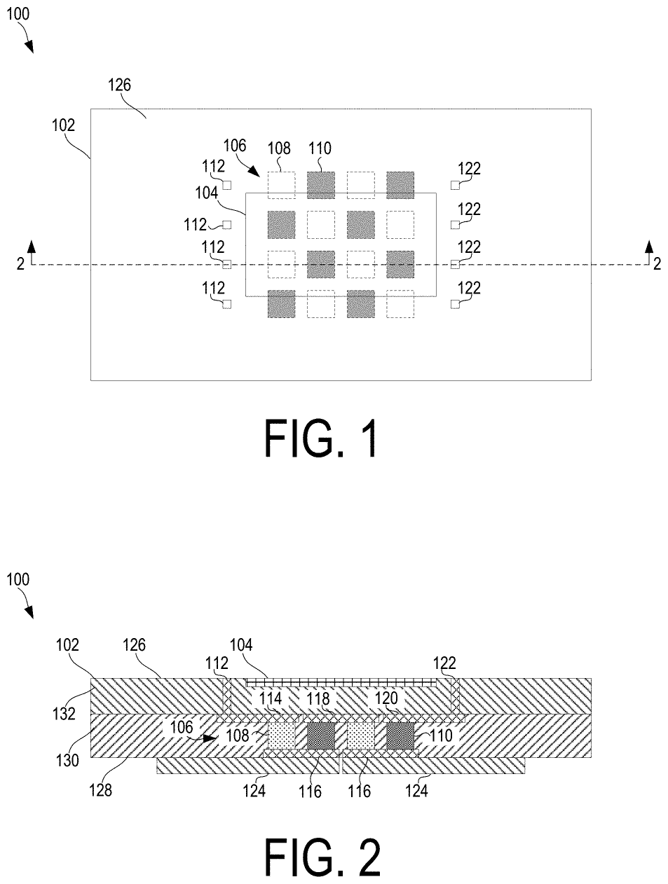

Referring now to FIGS. 1 and 2, in one embodiment, a system 100 includes an integrated circuit die 102 with one or more electronic components 104 formed in a top side 126 of the die 102. FIG. 1 shows a top-down view of the system 100, and FIG. 2 shows a cross-sectional view of the system 100. A thermoelectric cooler 106 is positioned in the back side 128, below the electronic component 104. In use, the thermoelectric cooler 106 can cool the die 102 in the region below the component 104.

The thermoelectric cooler 106 includes one or more p-type semiconductors 108 and one or more n-type semiconductors 110. In the illustrative embodiment, a through-silicon via 112 extends from the top side 126 of the die 102 to an upper interconnect conductor 114 connected to a p-type semiconductor 108. An upper interconnect conductor 118 connects another p-type semiconductor 108 to an n-type semiconductor 110. Lower interconnects 116 connect n-type semiconductors 110 to p-type semiconductors 108. Another upper connect conductor 120 connects a p-type semiconductor 108 to a through-silicon via 122.

In use, in one embodiment, current flows from the through-silicon via 112, to the upper interconnect conductor 114, through a p-type semiconductor 108, through a lower interconnect conductor 116, through an n-type semiconductor 110, through an upper interconnect 118, through another p-type semiconductor 108, through a lower interconnect conductor 116, through an n-type semiconductor 110, through an upper interconnect conductor 120, and through a through-silicon via 122. As current passes from the via 112 to the via 122, heat is transferred from the area of thermoelectric cooler 106 closer to the top side 126 towards the area of the thermoelectric cooler 106 closer to the back side 128.

In the illustrative embodiment, each row of n-type semiconductors 110 and p-type semiconductors 108 shown in the top-down view of FIG. 1 form a separate circuit. In some rows, depending on the ordering of n-type semiconductors 110 and p-type semiconductors 108, current can flow from the via 122 to the via 112. In other embodiments, a two-dimensional array of n-type semiconductors 110 and p-type semiconductors 108 may be connected by interconnects, with current flowing from one via 112 to the other via 122 through multiple rows of n-type semiconductors 110 and p-type semiconductors 108.

One or more heat sinks 124 are positioned on the back side 128 of the die 102. A layer of thermal paste or other thermal interface material may be between the heat sinks 124 and the back side 128 of the die 102. It should be appreciated that the lower interconnect conductors 116 shown in FIG. 2 are at different voltages. In the illustrative embodiment, heat sinks 124 may be in electrical contact with the interconnect conductors 116. As such, the heat sinks 124 may need to be isolated from each other. In other embodiments, the interconnect conductors 116 may be electrically isolated and thermally coupled to the heat sink(s) 124, allowing for one heat sink 124 to conduct from both interconnect conductors 116 shown in FIG. 2.

The electronic component 104 may be any suitable component. In one embodiment, the electronic component 104 is a gallium nitride power amplifier to amplify a radio-frequency (RF) signal. In some embodiments, the electronic component 104 may include a power RF amplifier made from any suitable III-V compound semiconductor. Additionally or alternatively, in other embodiments, the electronic components 104 may be embodied as or otherwise include logic circuitry, analog circuitry, power circuitry such as a voltage regulator, etc. The electronic components 104 may form part of a processor die, a memory die, etc.

The n-type semiconductors 110 and p-type semiconductors 108 may be any suitable material. In the illustrative embodiment, the n-type semiconductors 110 and p-type semiconductors 108 are doped polysilicon. In other embodiments, the n-type semiconductors 110 and p-type semiconductors 108 may be doped silicon-germanium, bismuth telluride, or any other suitable material. The n-type semiconductors 110 and p-type semiconductors 108 may have any suitable dimensions, such as a length and/or width of 2-50 micrometers, with a distance of 5-20 micrometers between the n-type semiconductors 110 and p-type semiconductors 108. Each n-type semiconductors 110 and p-type semiconductors 108 may have any suitable thickness, such as 10-100 nanometers. The thermoelectric cooler 106 may include any suitable number of n-type semiconductors 110 and p-type semiconductors 108, such as 2-1,000 n-type semiconductors 110 and p-type semiconductors 108.

Although the die 102 shows a single region cooled by a thermoelectric cooler 106, it should be appreciated that, in some embodiments, several different regions of the die 102 may be cooled by separate thermoelectric coolers 106.

In the illustrative embodiments, the various interconnects 112, 114, 116, 118, 120, 122 may be any suitable material, such as copper or other high-electrical-conductivity metal or other material.

The heat sink(s) 124 may be any suitable material with a high thermal conductivity, such as copper, aluminum, or other metal. The heat sink(s) 124 may have an array of fins to facilitate heat transfer to air, with one or more fans to blow air across the fins. In some embodiments, the heat sink(s) 124 may be cooled by water or another liquid.

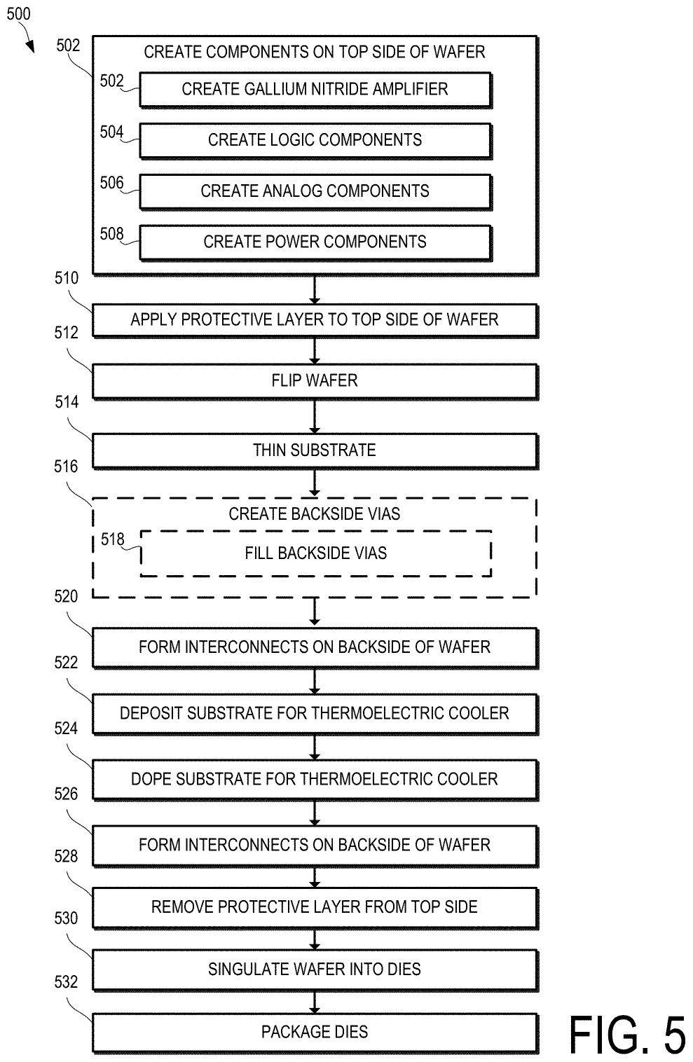

In the illustrative embodiment, the substrate 132 is silicon, and the one or more components 104 are partially formed from silicon in the substrate 132. In the illustrative embodiment, an underlying layer 130 is formed by techniques such as deposition or epitaxial growth on the substrate 132 as part of manufacturing the thermoelectric cooler 106, as described in more detail below in regard to FIG. 5. The substrate 132 may be any suitable material, such as polysilicon, silicon-germanium, or bismuth telluride.

As used herein, the “top side” 126 of the die 102 refers to an outer surface of the die 102 and a region below the outer surface. The illustrative die 102 is much thinner in one dimension than the other two, and the top side 126 refers to a surface extending along the two larger dimensions of the die 102 and a region below that surface. The “top side” 126 may, in some embodiments, be, e.g., oriented on the bottom of the die 102, depending on the orientation of the die 102. The back side 128 is opposite the top side 126. As used herein, a component (such as the component 104 or thermoelectric cooler 106) that is “formed in” or is “in” a top side 126 (or back side 128) of the die 102 refers to a component that is partially or completely formed from the substrate material 132 (or layer material 130).

The die 102 may be packaged with various other components, such as an interconnect layer on top of the top side 126 or back side 128 of the die, one or more other dies, a heat spreader, a lid, etc. The die 102 may form a part of any suitable package, such as a processor, a memory device, a system-on-a-chip, a graphics processing unit, a field-programmable gate array, an application-specific integrated circuit, or any other suitable package.

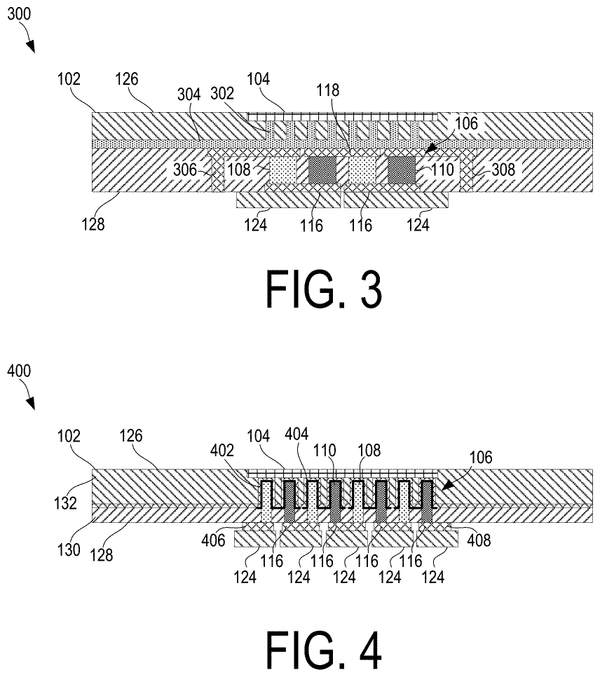

Referring now to FIG. 3, in one embodiment, a system 300 includes a die 102 with a component 104 in a top side 126 and a thermoelectric cooler 106 on a back side 128. FIG. 3 shows a side cross-sectional view of the system 300. Various components of the system 300 (and system 400 etc.) may be similar to those of the system 100. For example, the die 102, the component 104, p-type semiconductors 108, the n-type semiconductors 110, etc., of the system 300 may be similar or the same as the corresponding component of the system 100. A description of those components will not be repeated in the interest of clarity. The system 300 may include a two-dimensional grid of p-type semiconductors 108 and n-type semiconductors 110, similar to the system 100 as shown in FIG. 1.

The system 300 includes one or more vias 302 that extend from or near interconnect conductors 118 of the thermoelectric cooler 106 to or near the component 104. The one or more vias 302 may be filled with a thermally conductive material, such as diamond, copper, or aluminum nitride. The vias 302 may extend to a plane 304 of thermally conductive material above the thermoelectric cooler 106. The vias 302 may conduct heat from the component 104 to the thermoelectric cooler 106, improving the cooling ability of the thermoelectric cooler 106.

In the illustrative embodiment, a via 306 extends from the back side 128 to the top of a p-type semiconductor 108. Similarly, a via 308 extends from the top of an n-type semiconductor 110. The vias 306, 308 allow the thermoelectric cooler 106 to be connected to a power source on the back side 128 of the die 102, which may be preferred in there are other connections or obstacles on the top side 126 of the die 102.

Referring now to FIG. 4, in one embodiment, a system 400 includes a die 102 with a component 104 in a top side 126 and a thermoelectric cooler 106 in a back side 128. FIG. 4 shows a side cross-sectional view of the system 400. The system 400 may include a two-dimensional grid of p-type semiconductors 108 and n-type semiconductors 110, similar to the system 100 as shown in FIG. 1.

The system 400 includes p-type semiconductors 108 and n-type semiconductors 110 that extend into the substrate 132 in which the component 104 is defined. As such, the thermoelectric cooler 106 formed by the p-type semiconductors 108 and n-type semiconductors 110 can conduct heat away more effectively from the component 104. In the illustrative embodiment, conductors 404 are defined around a top portion of the p-type semiconductors 108 and n-type semiconductors 110. In some embodiments, a layer 402 of a thermally conductive and electrically insulative material such as diamond or aluminum nitride surrounds the conductors 404 and/or the p-type semiconductors 108 and n-type semiconductors 110, further improving the cooling capability of the thermoelectric cooler 106. Conductors 406, 408 can be used to send current into and out of the thermoelectric cooler 106.

Referring now to FIG. 5, in one embodiment, a flowchart for a method 500 for creating the system 100, 300, or 400 is shown. The method 500 may be executed by a technician and/or by one or more automated machines. In some embodiments, one or more machines may be programmed to do some or all of the steps of the method 500. Such a machine may include, e.g., a memory, a processor, data storage, etc. The memory and/or data storage may store instructions that, when executed by the machine, causes the machine to perform some or all of the steps of the method 500. The method 500 may use any suitable set of techniques that are used in semiconductor processing, such as chemical vapor deposition, atomic layer deposition, physical layer deposition, molecular beam epitaxy, layer transfer, photolithography, ion implantation, dry etching, wet etching, thermal treatments, flip chip, layer transfer, magnetron sputter deposition, pulsed laser deposition, etc. It should be appreciated that the method 500 is merely one embodiment of a method to create the system 100, 300, or 400, and other methods may be used to create the system 100, 300, or 400. In some embodiments, steps of the method 500 may be performed in a different order than that shown in the flowchart.

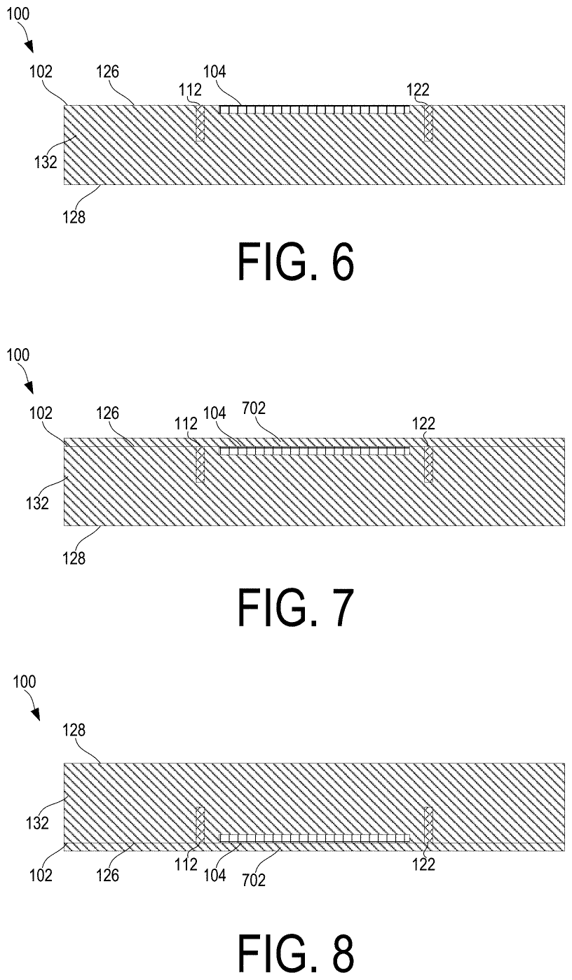

The method 500 begins in block 502, in which one or more components 104 are created on a top side 126 of a wafer, as shown in FIG. 6. In the illustrative embodiment, the wafer is a silicon wafer with a diameter of, e.g., 200-300 millimeters. In block 502, a gallium nitride amplifier may be created as a component 104. In block 504, one or more logic gates (transistors, memory cells, processor units, etc.) may be created as a component 104. In block 506, one or more analog components may be created as a component 104. In block 508, one or more power components, such as a voltage regulator, may be created as a component. In the illustrative embodiment, one or more through silicon vias 112, 122 are created partially or totally through the silicon substrate 132.

In block 510, as shown in FIG. 7, a protective layer 702 is applied to the wafer, covering and protecting the components 104 on the top side 126 of the wafer. In block 512, as shown in FIG. 8, the wafer is flipped, allowing the back side 128 of the wafer to be processed.

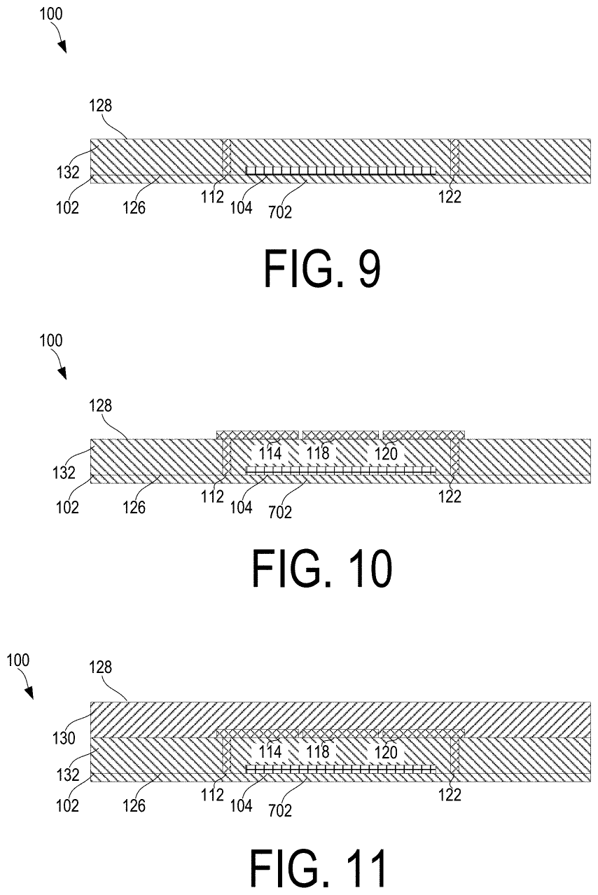

In block 514, as shown in FIG. 9, the substrate 132 of the wafer is thinned, such as by chemical etching or mechanical polishing. The wafer may be thinned from, e.g., 750 micrometers to, e.g., anywhere from 500-50 micrometers. As a result of the thinning, a distance between the one or more components 104 formed on the top side 126 of the wafer and the thermoelectric cooler 106 to be formed on the back side 128 of the wafer may have a distance of, e.g., 50-500 micrometers between them. In some embodiments, the wafer may not be thinned.

In block 516, in some embodiments, back side vias are created, such as those shown in FIGS. 3 & 4. In block 518, the back side vias may be filled. The back side vias may be filled with, e.g., diamond, copper, aluminum nitride, or other material. The back side vias may be filled using any suitable technique, such as chemical vapor deposition. In some embodiments, n-type semiconductors 110 and p-type semiconductors 108 may fill the back side vias, as shown in FIG. 4.

In block 520, interconnect conductors 114, 118, 120 are formed on the back side 128 of the wafers, as shown in FIG. 10. In block 522, a layer 130 for a thermoelectric cooler 106 is deposited, as shown in FIG. 11. The layer 130 may be any suitable material in which a thermoelectric cooler 106 may be made, such as polysilicon, silicon-germanium, bismuth telluride, etc.

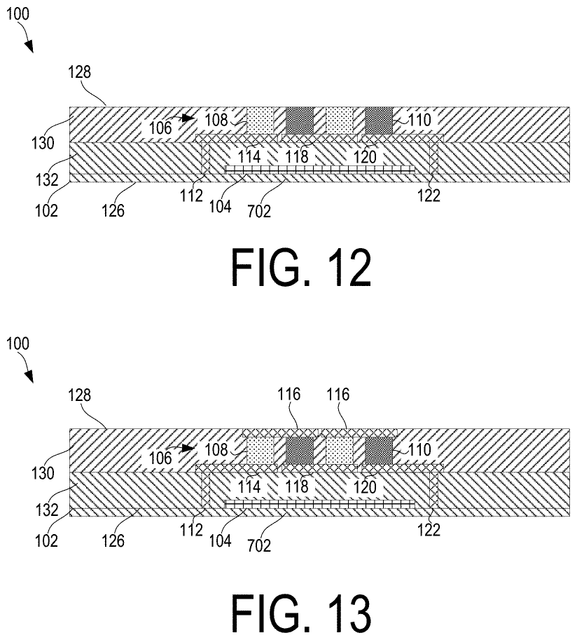

In block 524, the layer 130 is doped to create n-type semiconductors 110 and p-type semiconductors 108, as shown in FIG. 12. The n-type semiconductors 110 and p-type semiconductors 108 may be created by lithographically patterning a mask for the n-type semiconductors 110, doping the layer 130 to create the n-type semiconductors 110, lithographically patterning a mask for the p-type semiconductors 108, doping the layer 130 to create the p-type semiconductors 108, and activating the dopants.

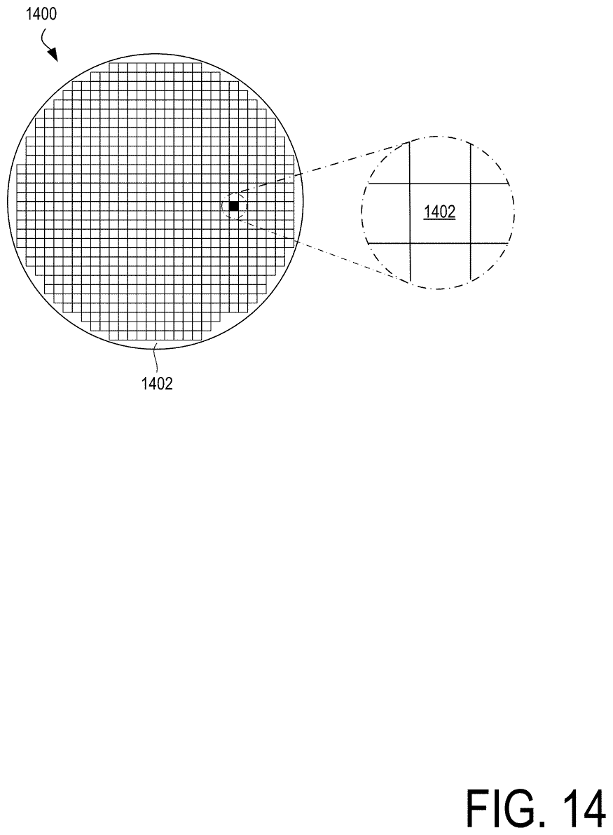

In block 526, interconnects 116 are formed on the back side 128 of the wafer, as shown in FIG. 13. In block 528, the protective layer 702 can be removed. In block 530, the wafer is singulated into dies 102.

In block 532, the dies 102 may be packaged with other components, such as a circuit board or substrate, other dies, heat spreaders, redistribution layers, etc., into a package. The package may then be integrated into, e.g., a circuit board, a computing device, etc. A heat sink may be applied directly or indirectly to the die 102 to remove heat transferred by the thermoelectric cooler 106.

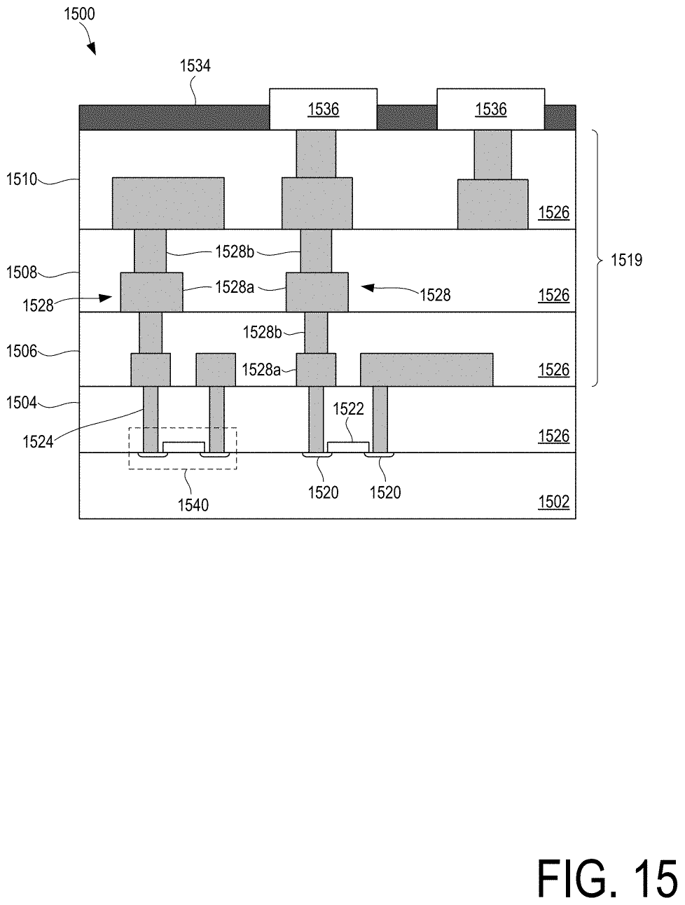

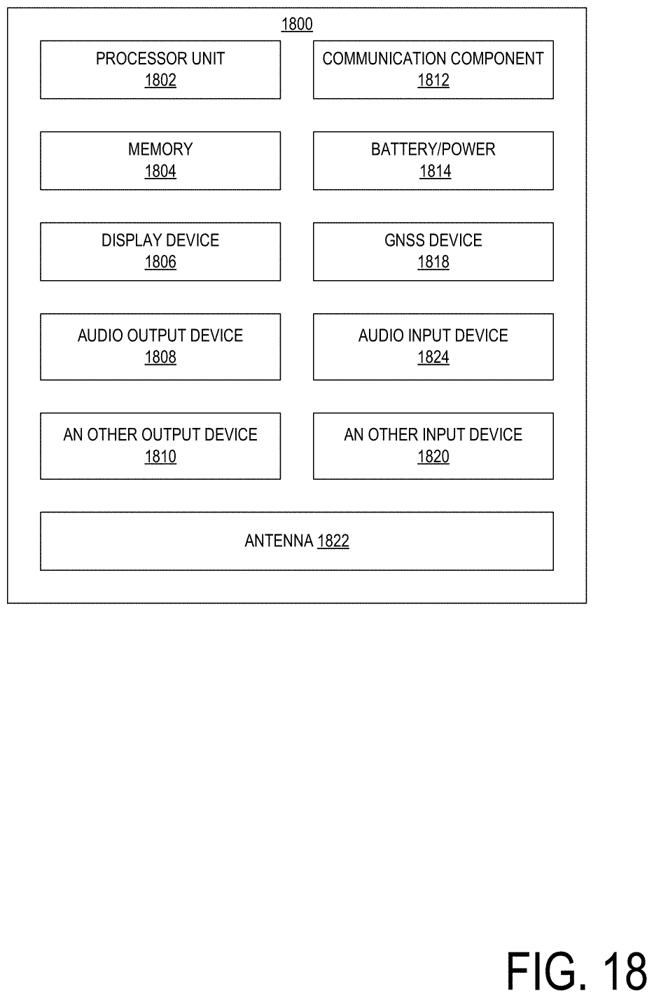

FIG. 14 is a top view of a wafer 1400 and dies 1402 that may be included in any of the systems 100 disclosed herein (e.g., as any suitable ones of the dies 102). The wafer 1400 may be composed of semiconductor material and may include one or more dies 1402 having integrated circuit structures formed on a surface of the wafer 1400. The individual dies 1402 may be a repeating unit of an integrated circuit product that includes any suitable integrated circuit. After the fabrication of the semiconductor product is complete, the wafer 1400 may undergo a singulation process in which the dies 1402 are separated from one another to provide discrete “chips” of the integrated circuit product. The die 1402 may be any of the die 102 disclosed herein. The die 1402 may include one or more transistors (e.g., some of the transistors 1540 of FIG. 15, discussed below), supporting circuitry to route electrical signals to the transistors, passive components (e.g., signal traces, resistors, capacitors, or inductors), and/or any other integrated circuit components. In some embodiments, the wafer 1400 or the die 1402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1402. For example, a memory array formed by multiple memory devices may be formed on a same die 1402 as a processor unit (e.g., the processor unit 1802 of FIG. 18) or other logic that is configured to store information in the memory devices or execute instructions stored in the memory array. Various ones of the systems 100, 300, etc. disclosed herein may be manufactured using a die-to-wafer assembly technique in which some dies 102 are attached to a wafer 1400 that include others of the dies 102, and the wafer 1400 is subsequently singulated.

FIG. 15 is a cross-sectional side view of an integrated circuit device 1500 that may be included in any of the systems disclosed herein (e.g., in any of the dies 102). One or more of the integrated circuit devices 1500 may be included in one or more dies 1402 (FIG. 14). The integrated circuit device 1500 may be formed on a die substrate 1502 (e.g., the wafer 1400 of FIG. 14) and may be included in a die (e.g., the die 1402 of FIG. 14). The die substrate 1502 may be a semiconductor substrate composed of semiconductor material systems including, for example, n-type or p-type materials systems (or a combination of both). The die substrate 1502 may include, for example, a crystalline substrate formed using a bulk silicon or a silicon-on-insulator (SOI) substructure. In some embodiments, the die substrate 1502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1502. Although a few examples of materials from which the die substrate 1502 may be formed are described here, any material that may serve as a foundation for an integrated circuit device 1500 may be used. The die substrate 1502 may be part of a singulated die (e.g., the dies 1402 of FIG. 14) or a wafer (e.g., the wafer 1400 of FIG. 14).

The integrated circuit device 1500 may include one or more device layers 1504 disposed on the die substrate 1502. The device layer 1504 may include features of one or more transistors 1540 (e.g., metal oxide semiconductor field-effect transistors (MOSFETs)) formed on the die substrate 1502. The transistors 1540 may include, for example, one or more source and/or drain (S/D) regions 1520, a gate 1522 to control current flow between the S/D regions 1520, and one or more S/D contacts 1524 to route electrical signals to/from the S/D regions 1520. The transistors 1540 may include additional features not depicted for the sake of clarity, such as device isolation regions, gate contacts, and the like. The transistors 1540 are not limited to the type and configuration depicted in FIG. 15 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

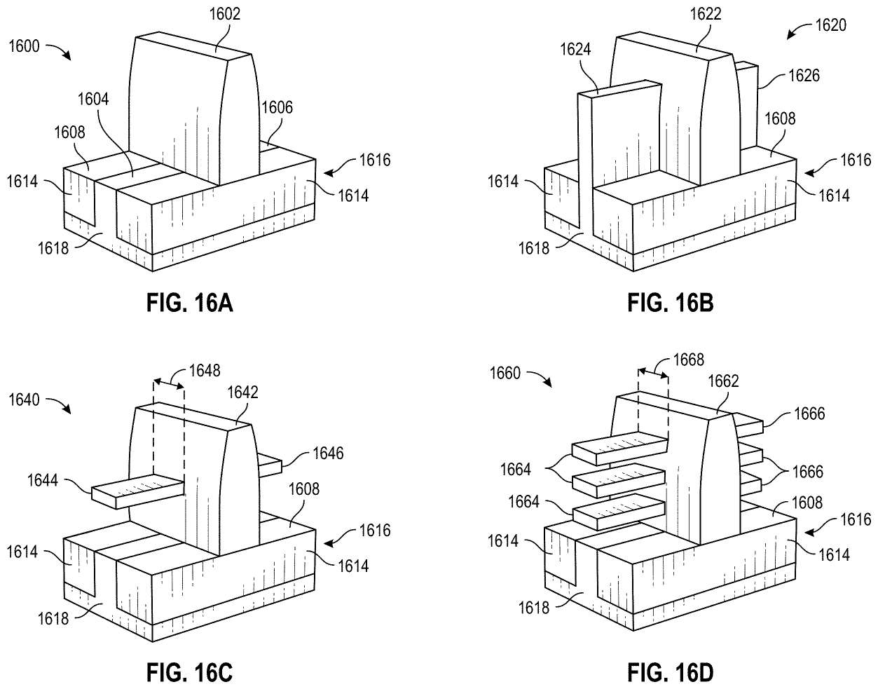

FIGS. 16A-16D are simplified perspective views of example planar, FinFET, gate-all-around, and stacked gate-all-around transistors. The transistors illustrated in FIGS. 16A-16D are formed on a substrate 1616 having a surface 1608. Isolation regions 1614 separate the source and drain regions of the transistors from other transistors and from a bulk region 1618 of the substrate 1616.

FIG. 16A is a perspective view of an example planar transistor 1600 comprising a gate 1602 that controls current flow between a source region 1604 and a drain region 1606. The transistor 1600 is planar in that the source region 1604 and the drain region 1606 are planar with respect to the substrate surface 1608.

FIG. 16B is a perspective view of an example FinFET transistor 1620 comprising a gate 1622 that controls current flow between a source region 1624 and a drain region 1626. The transistor 1620 is non-planar in that the source region 1624 and the drain region 1626 comprise “fins” that extend upwards from the substrate surface 1628. As the gate 1622 encompasses three sides of the semiconductor fin that extends from the source region 1624 to the drain region 1626, the transistor 1620 can be considered a tri-gate transistor. FIG. 16B illustrates one S/D fin extending through the gate 1622, but multiple S/D fins can extend through the gate of a FinFET transistor.

FIG. 16C is a perspective view of a gate-all-around (GAA) transistor 1640 comprising a gate 1642 that controls current flow between a source region 1644 and a drain region 1646. The transistor 1640 is non-planar in that the source region 1644 and the drain region 1646 are elevated from the substrate surface 1628.

FIG. 16D is a perspective view of a GAA transistor 1660 comprising a gate 1662 that controls current flow between multiple elevated source regions 1664 and multiple elevated drain regions 1666. The transistor 1660 is a stacked GAA transistor as the gate controls the flow of current between multiple elevated S/D regions stacked on top of each other. The transistors 1640 and 1660 are considered gate-all-around transistors as the gates encompass all sides of the semiconductor portions that extends from the source regions to the drain regions. The transistors 1640 and 1660 can alternatively be referred to as nanowire, nanosheet, or nanoribbon transistors depending on the width (e.g., widths 1648 and 1668 of transistors 1640 and 1660, respectively) of the semiconductor portions extending through the gate.

Returning to FIG. 15, a transistor 1540 may include a gate 1522 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1540 along the source-channel-drain direction, the gate electrode may consist of a U-shaped structure that includes a bottom portion substantially parallel to the surface of the die substrate 1502 and two sidewall portions that are substantially perpendicular to the top surface of the die substrate 1502. In other embodiments, at least one of the metal layers that form the gate electrode may simply be a planar layer that is substantially parallel to the top surface of the die substrate 1502 and does not include sidewall portions substantially perpendicular to the top surface of the die substrate 1502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1520 may be formed within the die substrate 1502 adjacent to the gate 1522 of individual transistors 1540. The S/D regions 1520 may be formed using an implantation/diffusion process or an etching/deposition process, for example. In the former process, dopants such as boron, aluminum, antimony, phosphorous, or arsenic may be ion-implanted into the die substrate 1502 to form the S/D regions 1520. An annealing process that activates the dopants and causes them to diffuse farther into the die substrate 1502 may follow the ion-implantation process. In the latter process, the die substrate 1502 may first be etched to form recesses at the locations of the S/D regions 1520. An epitaxial deposition process may then be carried out to fill the recesses with material that is used to fabricate the S/D regions 1520. In some implementations, the S/D regions 1520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1520 may be formed using one or more alternate semiconductor materials such as germanium or a group III-V material or alloy. In further embodiments, one or more layers of metal and/or metal alloys may be used to form the S/D regions 1520.

Electrical signals, such as power and/or input/output (I/O) signals, may be routed to and/or from the devices (e.g., transistors 1540) of the device layer 1504 through one or more interconnect layers disposed on the device layer 1504 (illustrated in FIG. 15 as interconnect layers 1506-1510). For example, electrically conductive features of the device layer 1504 (e.g., the gate 1522 and the S/D contacts 1524) may be electrically coupled with the interconnect structures 1528 of the interconnect layers 1506-1510. The one or more interconnect layers 1506-1510 may form a metallization stack (also referred to as an “ILD stack”) 1519 of the integrated circuit device 1500.

The interconnect structures 1528 may be arranged within the interconnect layers 1506-1510 to route electrical signals according to a wide variety of designs; in particular, the arrangement is not limited to the particular configuration of interconnect structures 1528 depicted in FIG. 15. Although a particular number of interconnect layers 1506-1510 is depicted in FIG. 15, embodiments of the present disclosure include integrated circuit devices having more or fewer interconnect layers than depicted.

In some embodiments, the interconnect structures 1528 may include lines 1528a and/or vias 1528b filled with an electrically conductive material such as a metal. The lines 1528a may be arranged to route electrical signals in a direction of a plane that is substantially parallel with a surface of the die substrate 1502 upon which the device layer 1504 is formed. The vias 1528b may be arranged to route electrical signals in a direction of a plane that is substantially perpendicular to the surface of the die substrate 1502 upon which the device layer 1504 is formed. In some embodiments, the vias 1528b may electrically couple lines 1528a of different interconnect layers 1506-1510 together.

The interconnect layers 1506-1510 may include a dielectric material 1526 disposed between the interconnect structures 1528, as shown in FIG. 15. In some embodiments, dielectric material 1526 disposed between the interconnect structures 1528 in different ones of the interconnect layers 1506-1510 may have different compositions; in other embodiments, the composition of the dielectric material 1526 between different interconnect layers 1506-1510 may be the same. The device layer 1504 may include a dielectric material 1526 disposed between the transistors 1540 and a bottom layer of the metallization stack as well. The dielectric material 1526 included in the device layer 1504 may have a different composition than the dielectric material 1526 included in the interconnect layers 1506-1510; in other embodiments, the composition of the dielectric material 1526 in the device layer 1504 may be the same as a dielectric material 1526 included in any one of the interconnect layers 1506-1510.

A first interconnect layer 1506 (referred to as Metal 1 or “M1”) may be formed directly on the device layer 1504. In some embodiments, the first interconnect layer 1506 may include lines 1528a and/or vias 1528b, as shown. The lines 1528a of the first interconnect layer 1506 may be coupled with contacts (e.g., the S/D contacts 1524) of the device layer 1504. The vias 1528b of the first interconnect layer 1506 may be coupled with the lines 1528a of a second interconnect layer 1508.

The second interconnect layer 1508 (referred to as Metal 2 or “M2”) may be formed directly on the first interconnect layer 1506. In some embodiments, the second interconnect layer 1508 may include via 1528b to couple the lines 1528 of the second interconnect layer 1508 with the lines 1528a of a third interconnect layer 1510. Although the lines 1528a and the vias 1528b are structurally delineated with a line within individual interconnect layers for the sake of clarity, the lines 1528a and the vias 1528b may be structurally and/or materially contiguous (e.g., simultaneously filled during a dual-damascene process) in some embodiments.

The third interconnect layer 1510 (referred to as Metal 3 or “M3”) (and additional interconnect layers, as desired) may be formed in succession on the second interconnect layer 1508 according to similar techniques and configurations described in connection with the second interconnect layer 1508 or the first interconnect layer 1506. In some embodiments, the interconnect layers that are “higher up” in the metallization stack 1519 in the integrated circuit device 1500 (i.e., farther away from the device layer 1504) may be thicker that the interconnect layers that are lower in the metallization stack 1519, with lines 1528a and vias 1528b in the higher interconnect layers being thicker than those in the lower interconnect layers.

The integrated circuit device 1500 may include a solder resist material 1534 (e.g., polyimide or similar material) and one or more conductive contacts 1536 formed on the interconnect layers 1506-1510. In FIG. 15, the conductive contacts 1536 are illustrated as taking the form of bond pads. The conductive contacts 1536 may be electrically coupled with the interconnect structures 1528 and configured to route the electrical signals of the transistor(s) 1540 to external devices. For example, solder bonds may be formed on the one or more conductive contacts 1536 to mechanically and/or electrically couple an integrated circuit die including the integrated circuit device 1500 with another component (e.g., a printed circuit board). The integrated circuit device 1500 may include additional or alternate structures to route the electrical signals from the interconnect layers 1506-1510; for example, the conductive contacts 1536 may include other analogous features (e.g., posts) that route the electrical signals to external components.

In some embodiments in which the integrated circuit device 1500 is a double-sided die, the integrated circuit device 1500 may include another metallization stack (not shown) on the opposite side of the device layer(s) 1504. This metallization stack may include multiple interconnect layers as discussed above with reference to the interconnect layers 1506-1510, to provide conductive pathways (e.g., including conductive lines and vias) between the device layer(s) 1504 and additional conductive contacts (not shown) on the opposite side of the integrated circuit device 1500 from the conductive contacts 1536.

In other embodiments in which the integrated circuit device 1500 is a double-sided die, the integrated circuit device 1500 may include one or more through silicon vias (TSVs) through the die substrate 1502; these TSVs may make contact with the device layer(s) 1504, and may provide conductive pathways between the device layer(s) 1504 and additional conductive contacts (not shown) on the opposite side of the integrated circuit device 1500 from the conductive contacts 1536. In some embodiments, TSVs extending through the substrate can be used for routing power and ground signals from conductive contacts on the opposite side of the integrated circuit device 1500 from the conductive contacts 1536 to the transistors 1540 and any other components integrated into the die 1500, and the metallization stack 1519 can be used to route I/O signals from the conductive contacts 1536 to transistors 1540 and any other components integrated into the die 1500.

Multiple integrated circuit devices 1500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

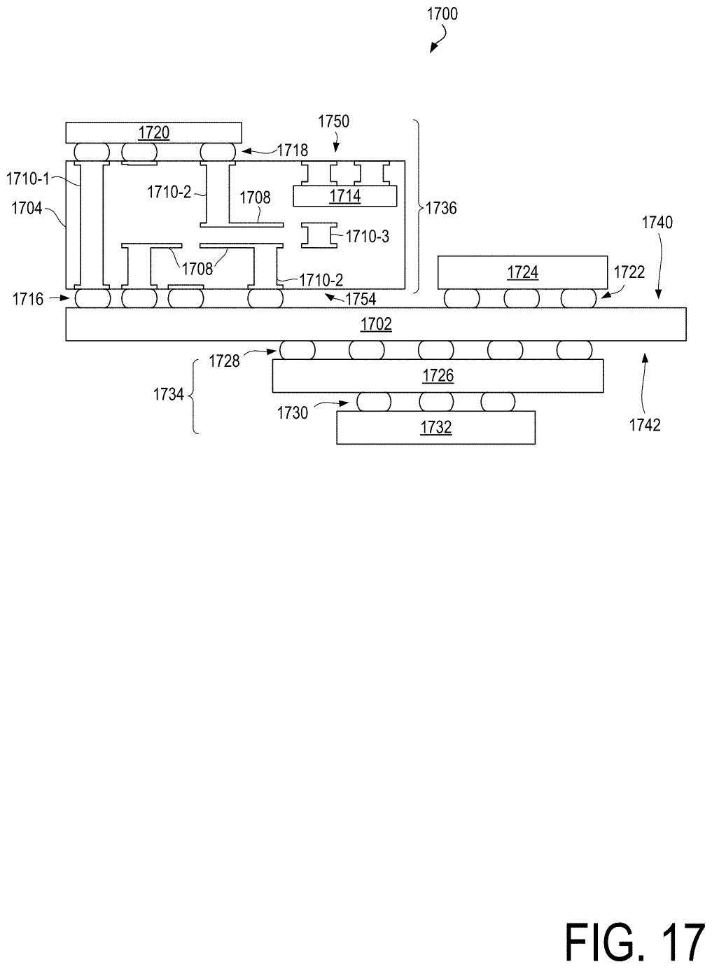

FIG. 17 is a cross-sectional side view of an integrated circuit device assembly 1700. The integrated circuit device assembly 1700 includes a number of components disposed on a circuit board 1702 (which may be a motherboard, system board, mainboard, etc.). The integrated circuit device assembly 1700 includes components disposed on a first face 1740 of the circuit board 1702 and an opposing second face 1742 of the circuit board 1702; generally, components may be disposed on one or both faces 1740 and 1742. Any of the integrated circuit components discussed below with reference to the integrated circuit device assembly 1700 may take the form of any suitable ones of the embodiments of the systems disclosed herein.

In some embodiments, the circuit board 1702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. The integrated circuit device assembly 1700 illustrated in FIG. 17 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 17), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1736 may include an integrated circuit component 1720 coupled to an interposer 1704 by coupling components 1718. The coupling components 1718 may take any suitable form for the application, such as the forms discussed above with reference to the coupling components 1716. Although a single integrated circuit component 1720 is shown in FIG. 17, multiple integrated circuit components may be coupled to the interposer 1704; indeed, additional interposers may be coupled to the interposer 1704. The interposer 1704 may provide an intervening substrate used to bridge the circuit board 1702 and the integrated circuit component 1720.

The integrated circuit component 1720 may be a packaged or unpacked integrated circuit product that includes one or more integrated circuit dies (e.g., the die 1402 of FIG. 14, the integrated circuit device 1500 of FIG. 15) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1720, a single monolithic integrated circuit die comprises solder bumps attached to contacts on the die. The solder bumps allow the die to be directly attached to the interposer 1704. The integrated circuit component 1720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1704 may spread connections to a wider pitch or reroute a connection to a different connection. For example, the interposer 1704 may couple the integrated circuit component 1720 to a set of ball grid array (BGA) conductive contacts of the coupling components 1716 for coupling to the circuit board 1702. In the embodiment illustrated in FIG. 17, the integrated circuit component 1720 and the circuit board 1702 are attached to opposing sides of the interposer 1704; in other embodiments, the integrated circuit component 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to through hole vias 1710-1 (that extend from a first face 1750 of the interposer 1704 to a second face 1754 of the interposer 1704), blind vias 1710-2 (that extend from the first or second faces 1750 or 1754 of the interposer 1704 to an internal metal layer), and buried vias 1710-3 (that connect internal metal layers).

In some embodiments, the interposer 1704 can comprise a silicon interposer. Through silicon vias (TSV) extending through the silicon interposer can connect connections on a first face of a silicon interposer to an opposing second face of the silicon interposer. In some embodiments, an interposer 1704 comprising a silicon interposer can further comprise one or more routing layers to route connections on a first face of the interposer 1704 to an opposing second face of the interposer 1704.

The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art. In embodiments where the interposer is a non-printed circuit board

The integrated circuit device assembly 1700 may include an integrated circuit component 1724 coupled to the first face 1740 of the circuit board 1702 by coupling components 1722. The coupling components 1722 may take the form of any of the embodiments discussed above with reference to the coupling components 1716, and the integrated circuit component 1724 may take the form of any of the embodiments discussed above with reference to the integrated circuit component 1720.

The integrated circuit device assembly 1700 illustrated in FIG. 17 includes a package-on-package structure 1734 coupled to the second face 1742 of the circuit board 1702 by coupling components 1728. The package-on-package structure 1734 may include an integrated circuit component 1726 and an integrated circuit component 1732 coupled together by coupling components 1730 such that the integrated circuit component 1726 is disposed between the circuit board 1702 and the integrated circuit component 1732. The coupling components 1728 and 1730 may take the form of any of the embodiments of the coupling components 1716 discussed above, and the integrated circuit components 1726 and 1732 may take the form of any of the embodiments of the integrated circuit component 1720 discussed above. The package-on-package structure 1734 may be configured in accordance with any of the package-on-package structures known in the art.

FIG. 18 is a block diagram of an example electrical device 1800 that may include one or more of the systems 100, 300, etc. disclosed herein. For example, any suitable ones of the components of the electrical device 1800 may include one or more of the integrated circuit device assemblies 1700, integrated circuit components 1720, integrated circuit devices 1500, or integrated circuit dies 1402 disclosed herein, and may be arranged in any of the systems 100, 300, etc. disclosed herein. A number of components are illustrated in FIG. 18 as included in the electrical device 1800, but any one or more of these components may be omitted or duplicated, as suitable for the application. In some embodiments, some or all of the components included in the electrical device 1800 may be attached to one or more motherboards mainboards, or system boards. In some embodiments, one or more of these components are fabricated onto a single system-on-a-chip (SoC) die.

Additionally, in various embodiments, the electrical device 1800 may not include one or more of the components illustrated in FIG. 18, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include one or more processor units 1802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1800 may include a memory 1804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1804 may include memory that is located on the same integrated circuit die as the processor unit 1802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1800 can comprise one or more processor units 1802 that are heterogeneous or asymmetric to another processor unit 1802 in the electrical device 1800. There can be a variety of differences between the processing units 1802 in a system in terms of a spectrum of metrics of merit including architectural, microarchitectural, thermal, power consumption characteristics, and the like. These differences can effectively manifest themselves as asymmetry and heterogeneity among the processor units 1802 in the electrical device 1800.

In some embodiments, the electrical device 1800 may include a communication component 1812 (e.g., one or more communication components). For example, the communication component 1812 can manage wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication component 1812 may manage wired communications, such as electrical, optical, or any other suitable communication protocols (e.g., IEEE 802.3 Ethernet standards). As noted above, the communication component 1812 may include multiple communication components. For instance, a first communication component 1812 may be dedicated to shorter-range wireless communications such as Wi-Fi or Bluetooth, and a second communication component 1812 may be dedicated to longer-range wireless communications such as global positioning system (GPS), EDGE, GPRS, CDMA, WiMAX, LTE, EV-DO, or others. In some embodiments, a first communication component 1812 may be dedicated to wireless communications, and a second communication component 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any embedded or wired or wirelessly connected external device that generates an audible indicator, such speakers, headsets, or earbuds.

The electrical device 1800 may include an audio input device 1824 (or corresponding interface circuitry, as discussed above). The audio input device 1824 may include any embedded or wired or wirelessly connected device that generates a signal representative of a sound, such as microphones, microphone arrays, or digital instruments (e.g., instruments having a musical instrument digital interface (MIDI) output). The electrical device 1800 may include a Global Navigation Satellite System (GNSS) device 1818 (or corresponding interface circuitry, as discussed above), such as a Global Positioning System (GPS) device. The GNSS device 1818 may be in communication with a satellite-based system and may determine a geolocation of the electrical device 1800 based on information received from one or more GNSS satellites, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1800 may be any other electronic device that processes data. In some embodiments, the electrical device 1800 may comprise multiple discrete physical components. Given the range of devices that the electrical device 1800 can be manifested as in various embodiments, in some embodiments, the electrical device 1800 can be referred to as a computing device or a computing system.

### Examples

Illustrative examples of the technologies disclosed herein are provided below. An embodiment of the technologies may include any one or more, and any combination of, the examples described below.

Example 1 includes an integrated circuit die comprising one or more electronic components in a top side of the integrated circuit die; and a thermoelectric cooler in a back side of the integrated circuit die.

Example 2 includes the subject matter of Example 1, and wherein the one or more electronic components are in a substrate, wherein the thermoelectric cooler is in a layer different from the substrate.

Example 3 includes the subject matter of any of Examples 1 and 2, and wherein the substrate comprises silicon, wherein the layer different from the substrate comprises polysilicon.

Example 4 includes the subject matter of any of Examples 1-3, and wherein the substrate comprises silicon, wherein the layer different from the substrate comprises silicon and germanium.

Example 5 includes the subject matter of any of Examples 1-4, and wherein the substrate comprises silicon, wherein the layer different from the substrate comprises bismuth and tellurium.

Example 6 includes the subject matter of any of Examples 1-5, and wherein a distance between the one or more electronic components and the thermoelectric cooler is less than 200 micrometers.

Example 7 includes the subject matter of any of Examples 1-6, and further including a pair of through-silicon vias extending from the top side to the thermoelectric cooler to provide current to the thermoelectric cooler.

Example 8 includes the subject matter of any of Examples 1-7, and wherein a heat sink is attached to the back side to dissipate heat from the thermoelectric cooler.

Example 9 includes the subject matter of any of Examples 1-8, and further including one or more vias extending from the thermoelectric cooler to the one or more electronic components.

Example 10 includes the subject matter of any of Examples 1-9, and wherein the one or more vias are filled with diamond.

Example 11 includes the subject matter of any of Examples 1-10, and wherein the one or more vias are filled with copper.

Example 12 includes the subject matter of any of Examples 1-11, and wherein the one or more vias are filled with aluminum nitride.

Example 13 includes the subject matter of any of Examples 1-12, and wherein the one or more electronic components comprise a compound semiconductor radio-frequency amplifier, wherein the compound semiconductor comprises elements from Group III and Group V of the periodic table.

Example 14 includes the subject matter of any of Examples 1-13, and wherein the one or more electronic components comprise logic, memory, and control circuitry.

Example 15 includes the subject matter of any of Examples 1-14, and wherein the one or more electronic components comprise power delivery circuitry.

Example 16 includes the subject matter of any of Examples 1-15, and wherein the one or more electronic components comprise analog and mixed signal circuitry.

Example 17 includes a system comprising an integrated circuit package comprising the integrated circuit die of any of Examples 1-16.

Example 18 includes the subject matter of Example 17, and wherein the integrated circuit package is a processor, further comprising one or more memory devices communicatively coupled to the processor.

Example 19 includes the subject matter of any of Examples 17 and 18, and wherein the system is a system-on-a-chip.

Example 20 includes a method comprising creating one or more electronic components on a top side of a wafer; and creating a thermoelectrical cooler on a back side of the wafer.

Example 21 includes the subject matter of Example 20, and wherein creating the thermoelectrical cooler on the back side of the wafer comprises flipping the wafer after creating the one or more electronic components on the top side of the wafer; growing an additional layer on a substrate on the back side of the wafer; and creating n-type semiconductors and p-type semiconductors in the additional layer.

Example 22 includes the subject matter of any of Examples 20 and 21, and wherein the substrate comprises silicon, wherein the additional layer is polysilicon.

Example 23 includes the subject matter of any of Examples 20-22, and wherein the substrate comprises silicon, wherein the additional layer comprises silicon and germanium.

Example 24 includes the subject matter of any of Examples 20-23, and wherein the substrate comprises silicon, wherein the additional layer comprises bismuth and tellurium.

Example 25 includes the subject matter of any of Examples 20-24, and further including applying a protective layer over the one or more electronic components before flipping the wafer.

Example 26 includes the subject matter of any of Examples 20-25, and further including thinning the substrate after flipping the wafer and before growing the additional layer.

Example 27 includes the subject matter of any of Examples 20-26, and further including creating a pair of through-silicon vias extending from the top side to the thermoelectric cooler to provide current to the thermoelectric cooler.

Example 28 includes the subject matter of any of Examples 20-27, and further including creating one or more vias extending from the thermoelectric cooler to the one or more electronic components.

Example 29 includes the subject matter of any of Examples 20-28, and further including filling the one or more vias with diamond.

Example 30 includes the subject matter of any of Examples 20-29, and further including filling the one or more vias with copper.

Example 31 includes the subject matter of any of Examples 20-30, and further including filling the one or more vias with aluminum nitride.

Example 32 includes the subject matter of any of Examples 20-31, and wherein the one or more electronic components comprise a compound semiconductor radio-frequency amplifier, wherein the compound semiconductor comprises elements from Group III and Group V of the periodic table.

Example 33 includes the subject matter of any of Examples 20-32, and wherein the one or more electronic components comprise logic, memory, and control circuitry.

Example 34 includes the subject matter of any of Examples 20-33, and wherein the one or more electronic components comprise power delivery circuitry.

Example 35 includes the subject matter of any of Examples 20-34, and wherein the one or more electronic components comprise analog and mixed signal circuitry.

Example 36 includes the subject matter of any of Examples 20-35, and further including singulating the wafer into one or more dies; and integrating the one or more dies into one or more packages.

1. An integrated circuit die comprising:
one or more electronic components in a top side of the integrated circuit die; and
a thermoelectric cooler in a back side of the integrated circuit die.

2. The integrated circuit die of claim 1, wherein the one or more electronic components are in a substrate, wherein the thermoelectric cooler is in a layer different from the substrate.

3. The integrated circuit die of claim 2, wherein the substrate comprises silicon, wherein the layer different from the substrate comprises polysilicon.

4. The integrated circuit die of claim 2, wherein the substrate comprises silicon, wherein the layer different from the substrate comprises silicon and germanium.

5. The integrated circuit die of claim 2, wherein the substrate comprises silicon, wherein the layer different from the substrate comprises bismuth and tellurium.

6. The integrated circuit die of claim 1, wherein a distance between the one or more electronic components and the thermoelectric cooler is less than 200 micrometers.

7. The integrated circuit die of claim 1, further comprising a pair of through-silicon vias extending from the top side to the thermoelectric cooler to provide current to the thermoelectric cooler.

8. The integrated circuit die of claim 1, wherein a heat sink is attached to the back side to dissipate heat from the thermoelectric cooler.

9. The integrated circuit die of claim 1, further comprising one or more vias extending from the thermoelectric cooler to the one or more electronic components.

10. The integrated circuit die of claim 9, wherein the one or more vias are filled with diamond.

11. The integrated circuit die of claim 9, wherein the one or more vias are filled with copper.

12. The integrated circuit die of claim 9, wherein the one or more vias are filled with aluminum nitride.

13. The integrated circuit die of claim 1, wherein the one or more electronic components comprise a compound semiconductor radio-frequency amplifier, wherein the compound semiconductor comprises elements from Group III and Group V of the periodic table.

14. The integrated circuit die of claim 1, wherein the one or more electronic components comprise logic, memory, and control circuitry.

15. The integrated circuit die of claim 1, wherein the one or more electronic components comprise power delivery circuitry.

16. The integrated circuit die of claim 1, wherein the one or more electronic components comprise analog and mixed signal circuitry.

17. A system comprising:
an integrated circuit package comprising the integrated circuit die of claim 1.

18. The system of claim 17, wherein the integrated circuit package is a processor, further comprising one or more memory devices communicatively coupled to the processor.

19. The system of claim 17, wherein the system is a system-on-a-chip.

20. A method comprising:
creating one or more electronic components on a top side of a wafer; and
creating a thermoelectrical cooler on a back side of the wafer.

21. The method of claim 20, wherein creating the thermoelectrical cooler on the back side of the wafer comprises:
flipping the wafer after creating the one or more electronic components on the top side of the wafer;
growing an additional layer on a substrate on the back side of the wafer; and
creating n-type semiconductors and p-type semiconductors in the additional layer.

22. The method of claim 21, wherein the substrate comprises silicon, wherein the additional layer is polysilicon.

23. The method of claim 21, further comprising applying a protective layer over the one or more electronic components before flipping the wafer.

24. The method of claim 21, further comprising thinning the substrate after flipping the wafer and before growing the additional layer.

25. The method of claim 20, further comprising creating one or more vias extending from the thermoelectric cooler to the one or more electronic components.
